(19) United States
(12) Patent Application Publication
(10) Pub. No.: US 2008/0093712 A1
(43) Pub. Date: Apr. 24, 2008

(54) Chip with Light Protection Layer

(75) Inventor: Christian Zenz, Graz (AT)

Correspondence Address: NXP, B.V.;NXP INTELLECTUAL PROPERTY DEPARTMENT, M/S41-SJ, 1109 MCKAY DRIVE, SAN JOSE, CA, 95131, US

(73) Assignee: KONINKLIJKE PHILIPS ELECTRONICS N.V., Eindhoven (NL)

(21) Appl. No.: 11/572,789

(22) PCT Filed: Jul. 20, 2006
(86) PCT No.: PCT/IB05/52426

§ 371 Date: Oct. 3, 2007

(30) Foreign Application Priority Data
Jul. 26, 2004 (EP) 04103562.7

(51) Int. Cl. H01L 23/552; H01L 21/31

(52) U.S. Cl. 257/659; 438/763; 257/E21.24; 257/E23.114

(57) ABSTRACT

In the case of a chip (1) having an integrated circuit (2), a dielectric mirror coating (3) having at least two dielectric layers (6, 7, . . . H, I, H) is applied as light protection means for the at least one integrated circuit (2) on at least one portion of the surface of the chip (1).

### FIELD OF THE INVENTION

The invention relates to a chip having at least one integrated circuit and having light protection means for the at least one integrated circuit.

The invention relates furthermore to a method for the manufacture of a chip having at least one integrated circuit and having light protection means for the at least one integrated circuit.

### BACKGROUND OF THE INVENTION

It is generally necessary to provide light protection for chips, since the semiconductors used in chips in general have a high light sensitivity in terms of the photoelectric effect.

Because of the semiconductor materials used, the problem arising with chips is that the functions of the chips can be radically influenced or actually prevented by the incidence on their unprotected surfaces of even small amounts of light in the UV, VIS and IR ranges, owing to the resulting charges generated. Furthermore, it is possible, by irradiation with light of a specific wavelength, deliberately to deactivate certain security circuits, such as those used for security chips, in order to hack into the chip (Japanese Tourist Attack). For this reason, chips normally have a light protection layer, which takes on the task of protection against light. Such a light protection layer is frequently realized by means of a black epoxy coating, which is applied as a finishing layer on the chip. Since light protection is achieved in this case by colorants, pigments or carbon particles that are admixed with the epoxy resin, certain minimum layer thicknesses are needed in order to achieve a satisfactorily high optical absorption. Yet such an epoxy coating has a thickness that is not suitable for realization of extremely thin chips, such as those used in radio frequency identification applications (RFID applications), since it renders the overall thickness of the chip too great. Furthermore, there is the risk of corrosion problems, since the added colorants in many cases have really high proportions of ions. In order to preclude such corrosion problems, ultra pure “colorants” can be used, but these are very expensive owing to complicated purification processes required for their manufacture. In addition, there is the problem that in most cases the application of the light protection layer cannot be integrated in the chip production process, but has to be carried out separately from the actual manufacture of the chip, since the materials and methods conventionally used for the manufacture of the light protection layer, for example, wet-chemical methods, represent a risk of contamination in the chip production process.

The document DE 198 40 251 A discloses a chip of the kind mentioned initially, which chip is manufactured from a semi-conducting substrate with a front face and a rear face, an integrated circuit being realized on the front face. Furthermore, on the front face there is provided a light protection layer, which extends over a region in which the integrated circuit is realized. The light protection layer in this case comprises metal or a semiconductor material having a lower band gap than silicon, for example, highly conductive silicide.

In the case of the known chip, however, it has proved a disadvantage that the conductive materials used to produce the light protection layer encourage the development of parasitic capacitance, which constitutes the danger that the mode of operation of the chip will be impaired. Owing to the small dimensions, this applies to an especially marked degree to RFID applications.

### OBJECT AND SUMMARY OF THE INVENTION

It is an object of the invention to avoid the disadvantages described above and occurring in the case of a chip of the kind specified in the first paragraph and in the case of a method of the kind described in the second paragraph, and to produce an improved chip and an improved method.

To achieve the above-mentioned object, in a chip in accordance with the invention inventive features are provided, so that a chip in accordance with the invention can be characterized in the manner specified hereafter, namely:

A chip having at least one integrated circuit and having light protection means for the at least one integrated circuit, a dielectric mirror coating having at least two dielectric layers being applied as light protection means on at least a portion of the surface of the chip.

To achieve the above-mentioned object, in a method in accordance with the invention inventive features are provided, so that a method in accordance with the invention can be characterized in the manner specified hereafter, namely:

A method for the manufacture of a chip having at least one integrated circuit and having light protection means for the at least one integrated circuit, wherein on at least a portion of the surface of the chip a dielectric mirror coating is applied as light protection means and wherein, for manufacture of the dielectric mirror coating, at least one dielectric layer having a high refractive index and one dielectric layer having a low refractive index is applied to the chip.

The advantage obtained by the features according to the invention is that in a very simple and cost-efficient manner optimum protection against incident light can be achieved for at least one integrated circuit of a chip, even a very flat chip, without the mode of operation of the at least one integrated circuit being adversely affected. Even at a layer thickness of a few μm, a dielectric mirror coating enables a very high reflectivity and hence a very good protection of the underlying layers of the chip against incident light radiation to be achieved over a very large spectral bandwidth. Furthermore, the solution according to the invention provides an opportunity for the properties of the light protection means to be designed in a very simple manner in accordance with given light protection requirements. Thus, the preferred spectral range in which reflectivity is to be greatest can be adjusted by defining the optical thickness of the individual dielectric layers of the dielectric mirror coating. Moreover, the use of dielectrics to produce the dielectric mirror coating offers the advantage that application of the dielectric mirror coating can be integrated in a simple manner in the chip manufacturing process, owing to the compatibility of these dielectric materials with the customary chip manufacturing processes.

The advantage gained in accordance with the measures of claim 2 and claim 6 is that optimum light protection is obtained on the side of the chip on which the at least one integrated circuit is exposed to direct effects of light. Moreover, the advantage is gained that an additional passivation of the integrated circuit with respect to mechanical and chemical influences can be dispensed with, since these tasks are performed by the dielectric mirror coating.

It has proved especially advantageous, however, if the measures according to claim 3 and claim 7 are provided. The advantage is thereby gained that even in the case of a flip chip application, a very effective light protection is provided for the chip according to the invention.

With the measures according to claim 4 and claim 8, the advantage is gained that if the outermost layer of the dielectric mirror coating adjoins air or another medium having a similarly low refractive index, a very good reflection behavior can be achieved.

These and other aspects of the invention are apparent from and will be elucidated, by way of non-limitative example, with reference to the embodiments described hereinafter.

### BRIEF DESCRIPTION OF THE DRAWINGS

In the drawings:

FIG. 1 shows schematically a chip according to the invention, namely in plan view onto the side of the chip on which an integrated circuit is realized.

FIG. 2 shows schematically a further chip according to the invention, namely in plan view onto the side of the chip opposite the side on which an integrated circuit is realized.

FIG. 3 shows in a schematic cross-sectional view a further chip according to the invention.

FIG. 4 shows in a schematic cross-sectional view a dielectric mirror coating and the reflection behavior thereof.

### DESCRIPTION OF EMBODIMENTS

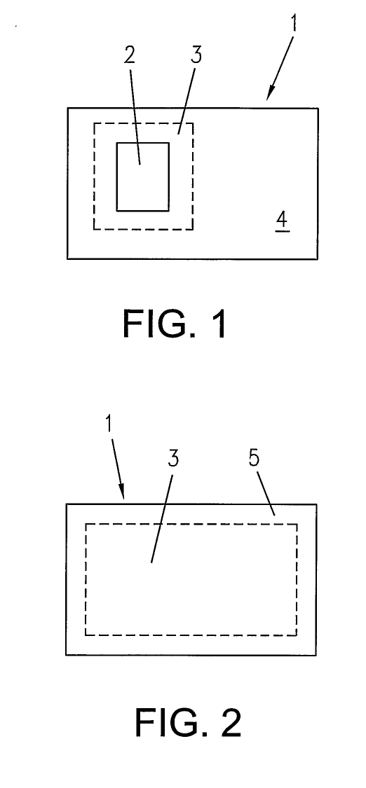

FIG. 1 shows a chip 1 according to the invention, which has an integrated circuit 2. In principle, several integrated circuits can also be realized independently of each other on the chip 1. The integrated circuit 2 is realized on a first side 4 of the chip 1, generally known as the “active side”, and is protected against the effects of light by a dielectric mirror coating 3 applied on the surface of the chip 1.

A relatively large number of dielectric mirror coatings have been known to those skilled in the art for a relatively long period of time from the literature. All dielectric mirror coatings have in common the fact they are composed of two or more dielectric λ/4 layers, immediately successive dielectric layers having a different refractive index. Relating to dielectric mirror coatings, the reader is referred by way of example to Matt Young, “Optik, Laser, Wellenleiter”; Springer, 1997; pp 160-161. Despite this fact, experts in the field of integrated circuit chips have never proposed the use of such dielectric mirror coatings in the case of chips having integrated circuits.

“Light” in the present context is understood to be not only light visible to humans, that is, a wavelength range from 380 nm to 780 nm, but also light from spectral ranges of the infrared and ultraviolet adjoining this range.

According to the embodiment shown in FIG. 1, the dielectric mirror coating 3 is applied on the first side 4 of the chip 1 directly onto the integrated circuit 2. This has the advantage that the dielectric mirror coating 3 also takes on the function of a passivation layer against mechanical and chemical influences on the integrated circuit 2, whereby the manufacture of the chip 1 is also simplified. It is important here that when the integrated circuit 2 is directly exposed to effects of light, as is the case when the chip 1 is mounted on a chip carrier with the first side 4 facing away from the chip carrier, at least the active elements of the integrated circuit 2, such as, for example, transistors, diodes and the like, are protected by means of the dielectric mirror coating 3. Above all, when the chip 1 is constructed as a “Quad Flat Package”, the integrated circuit 2 can be exposed to direct incidence of light.

FIG. 2 shows a chip 1; with this chip 1 the dielectric mirror coating 3 is applied on the second side 5 of the chip 1 opposite the first side 4 and generally called the “passive side”. This embodiment of the invention is above all of advantage when the chip 1 is provided for mounting on a chip carrier with the first side 4 facing towards the chip carrier, as is the case with a construction of the chip 1 as what is known as a flip chip.

The embodiments according to the invention just mentioned ensure that the dielectric mirror coating 3 is always arranged between the light incident upon the surface of the chip 1 and the integrated circuit 2.

The embodiments of the invention illustrated in FIGS. 1 and 2 can be realized both separately and jointly. Thus, both an application of the dielectric mirror coating 3 to the first side 4 and to the second side 5 of the chip 1 and an application of the dielectric mirror coating 3 to just one of the two sides 4 and 5 is possible.

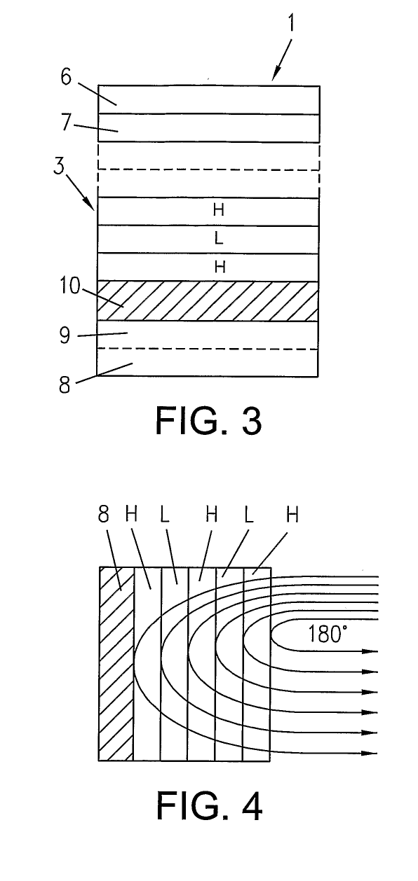

FIG. 3 shows the basic construction of a chip 1 according to the invention with the dielectric mirror coating 3. The chip 1 has a substrate 8, which comprises a semiconductor crystal, for example, doped silicon. The integrated circuit is realized in an active zone 9 of the substrate 8. A passivation layer 10, which protects the chip 1 from chemical influences and moisture, is applied over the integrated circuit, that is, over the active zone 9.

The dielectric mirror coating 3 is applied directly on the passivation layer 10. In the absence of such a passivation layer, the mirror coating 3 is applied directly on the active zone 9, that is, on parts of the active zone 9 of the chip 1 that are to be protected against incidence of light, the chip 1 having already been completed as far as circuit engineering is concerned. As already mentioned above, it is also possible for the dielectric mirror coating 3 to be applied additionally or exclusively on the second side 5 of the chip 1, depending on the preferred use and construction of the chip 1. It should be noted at this point that the ratio to one another of thicknesses of the individual layers 8, 9, 10, H, L, H, . . . 7, 6 illustrated in FIG. 3 is not to scale. The illustration serves merely to demonstrate a basic sequence of the individual layers 8, 9, 10, H, L, H, . . . 7, 6 of the chip 1. Thus, in particular the illustrated thickness ratio between the thickness of the active zone 9, the thickness of which normally lies in the nm—range, and the thickness of the layers 10, H, L, H, . . . 7, 6 lying above it, which thicknesses normally each range in the μm—range, does not correspond to the actual circumstances.

To produce the dielectric mirror coating 3 on the chip 1, virtually completely transparent dielectrics (e.g. SiO₂ and TiO₂) can be used in the wavelength range under consideration. When using dielectrics in the manufacture of the dielectric mirror coating 3 it is of advantage above all that these materials are compatible with the chip production process and are hence integrable without problems in the production process.

A dielectric shall be understood here to mean a substance that conducts no or hardly any current, that is, has a high resistivity (>10¹⁰ Ω). Dielectrics have a large energy band gap of in part more than 10 eV, giving a very low interaction with electromagnetic radiation over a broad spectral range. Depending on specification, dielectric thin-film materials for the manufacture of the dielectric mirror coating 3 are chosen in accordance with their optical, mechanical and chemical suitability.

To produce the dielectric mirror coating 3, layers H, L, H, . . . 7, 6 of dielectrics are applied alternately to the surface or to parts of the surface of the chip 1. Each layer H, L, H, . . . 7, 6 in this case comprises a dielectric, layers having a high and a low refractive index following one after another alternately. Preferably, the dielectric mirror coating 3 comprises layers of two different dielectrics. It is also possible, however, instead of a layer system of two dielectrics to provide a layer system of a plurality of different dielectrics in the case of a chip 1.

In FIGS. 3 and 4, the reference letter H denotes a dielectric layer having a high refractive index, this layer H being, for example, a layer of TiO₂ having a refractive index of 2.40. The reference letter L denotes a dielectric layer having a comparatively low refractive index, this layer L being, for example, a layer of SiO₂ having a refractive index of 1.46. Each of these dielectric layers H, L has, as is customary in dielectric mirror coatings, an optical thickness d of λ/4 (more accurately: d=λ/4n where n=refractive index of the layer). Since a phase change occurs at every second interface, the reflecting waves are superimposed constructively. With a plurality of dielectric layers H, L a reflection degree of more than 99.9% can therefore be achieved for a pre-determinable spectral range. The optimum number of these H, L—pairs for achieving the maximum possible reflectivity is dependent on the absorption and distribution of the layers H, L themselves. The sequence of the layers H having a high refractive index and the layers L having in comparison a lower refractive index can vary from the sequence illustrated in FIGS. 3 and 4 in dependence on the given requirements. Thus, the positions of the layers H, L can be interchanged, so that the layer sequence L-H-L-H-L . . . replaces the illustrated layer sequence H-L-H-L-H.

The dielectric mirror coating 3 can be realized even with two (2) to three (3) dielectric layers H, L, which can also be produced relatively inexactly. With a mirror coating 3 of this kind comprising two (2) to three (3) layers H, L it is already possible to achieve a reflectivity of 80% or more.

If the outermost dielectric layer 6 of the mirror coating 3 adjoins air or a medium having a low refractive index, then it is advantageous for this outermost dielectric layer 6 to have a higher refractive index than the inner dielectric layer 7 following immediately thereafter, since in this case a large proportion of the incident light is already reflected at the outermost dielectric layer 6.

The quality of the interfaces of the individual layers H, L of the dielectric mirror coating 3 is also important. By different coating techniques, it is possible to influence the properties of the individual layers and the constitution of the interfaces as determining factors for the overall layer system of the dielectric mirror coating 3. The preferred techniques for applying the dielectric layers to the surface of the chip 1 are here resistance deposition, electron beam vapor deposition, laser-assisted electron beam vapor deposition, ion beam-assisted vapor deposition and plasma ion-assisted vapor deposition. Moreover, the coating process can additionally be optimized by pre-heating of the chip 1.

With just relatively few dielectric layers H, L—even with two (2) to three (3) layers—a pre-determined degree of reflection for a pre-determinable wavelength range can be achieved with the dielectric mirror coating 3.

The mode of operation of the dielectric mirror coating 3 is illustrated in FIG. 4. Some of the incident light is reflected at each interface between two dielectric layers H, L. The reflection at each higher-refracting H results in a phase jump through 180°. The radiation reflected at the interfaces from high-refracting to low-refracting material does not have this phase jump. In combination with the optical thicknesses of the layers of λ/4, these circumstances ensure that the phase shift of the radiation superpositioning at the surface corresponds exactly to an uneven multiple of 180°. The superpositioning of the partial beams reflected at the interfaces is therefore constructive.

Primarily, the reflectance of the dielectric mirror coating 3 as far as its resonance wavelength is concerned depends only on the number of H, L—pairs, the ratio of the refractive indices of high-refracting and low-refracting materials and to a minor extent also on the refractive index of the substrate 8.

The reflectance of the dielectric mirror coating 3 is wavelength-dependent, the reflection in a region around the central wavelength being very high and reducing at larger and smaller wavelengths. The breadth of the highly-reflected spectral range largely depends on the refractive index ratios of the layer materials used. The higher are the refractive index ratios of the dielectric layer materials, the greater also is the spectral bandwidth of the dielectric mirror coating 3.

To summarize, the merit of the invention lies in rendering possible the realization of an effective light-protection means for chips, even for very thin chips, in a cost-effective and simple manner through the use of a dielectric mirror coating known per se in various forms in the field of chips having at least one integrated circuit.

1. A chip having at least one integrated circuit and having light protection means for the at least one integrated circuit, wherein a dielectric mirror coating having at least two dielectric layers is applied as light protection means on at least a portion of the surface of the chip.

2. A chip as claimed in claim 1, wherein the dielectric mirror coating is applied on at least a side of the chip on which the at least one integrated circuit is realized, at least over a region of the at least one integrated circuit, in which region active elements of the at least one integrated circuit are realized.

3. A chip as claimed in claim 1, wherein the dielectric mirror coating is applied at least on a side of the chip that lies opposite the side on which the at least one integrated circuit is realized.

4. A chip as claimed in claim 1, wherein the outermost dielectric layer of the dielectric mirror coating has a higher refractive index than an immediately proximate, inner dielectric layer.

5. A method for the manufacture of a chip having at least one integrated circuit and having light protection means for the at least one integrated circuit, wherein a dielectric mirror coating is applied as light protection means on at least a portion of the surface of the chip and wherein at least one dielectric layer having a high refractive index and a dielectric layer having a low refractive index are applied to the chip to provide the dielectric mirror coating.

6. A method as claimed in claim 5, wherein the dielectric mirror coating is applied on at least a side of the chip on which the at least one integrated circuit has already been realized, at least over a region of the at least one integrated circuit, in which region active elements of the at least one integrated circuit are realized.

7. A method as claimed in claim 5, wherein the dielectric mirror coating is applied on a side of the chip that lies opposite the side on which the at least one integrated circuit has already been realized.

8. A method as claimed in claim 5, wherein a layer having a higher refractive index than an immediately proximate, inner dielectric layer is applied as outermost dielectric layer of the dielectric mirror coating.
